(19) United States
(12) Patent Application Publication
(10) Pub. No.: US 2025/0336667 A1
(43) Pub. Date: Oct. 30, 2025

(54) AREA SELECTIVE DEPOSITION

(71) Applicant: ASM IP Holding B.V., Almere (NL)

(72) Inventors: James Huang, Chandler, AZ (US); Krzysztof Kamil Kachel, Chandler, AZ (US)

(21) Appl. No.: 19/188,247

(22) Filed: Apr. 24, 2025

Related U.S. Application Data
(60) Provisional application No. 63/639,954, filed on Apr. 29, 2024.

(51) Int. Cl. H01L 21/02; C23C 16/02; C23C 16/04; C23C 16/455

(52) U.S. Cl. CPC H01L 21/0228; C23C 16/0272; C23C 16/04; C23C 16/45527; H01L 21/0206; H01L 21/02211

(57) ABSTRACT

Disclosed is a method, system and apparatus for selective deposition of a material on a substrate. In an example, the substrate is provided in a reaction chamber and may comprise a first surface that comprises silicon (Si) and a second surface that comprises germanium (Ge). A passivation layer may be selectively deposited on the first surface with respect to the second surface. This can be achieved by contacting the substrate with a first precursor, which comprises an alkylaminosilane, during a first cyclic deposition sub-cycle. An inhibitor layer may be selectively deposited on the second surface relative to the first surface during a second cyclic deposition sub-cycle. Such selective deposition may include contacting the substrate with a first inhibitor precursor comprising an amine and a second inhibitor precursor comprising a dianhydride.

### CROSS-REFERENCE TO RELATED APPLICATIONS

This application is a nonprovisional of, and claims priority to and the benefit of, U.S. Provisional Patent Application No. 63/639,954, filed Apr. 29, 2024 and entitled “AREA SELECTIVE DEPOSITION,” which is hereby incorporated by reference herein.

### FIELD

The present disclosure relates to deposition of organic thin films, including selective deposition on a first surface of a substrate relative to a second surface.

### DESCRIPTION OF RELATED ART

Shrinking device dimensions in semiconductor manufacturing calls for new innovative processing approaches. Conventionally, patterning in semiconductor processing involves subtractive processes, in which blanket layers are deposited, masked by photolithographic techniques, and etched through openings in the mask. Additive patterning is also known, in which masking steps precede deposition of the materials of interest, such as patterning using lift-off techniques or damascene processing. In most cases, expensive multi-step lithographic techniques are applied for patterning.

Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing. A need exists for more efficient and reliable techniques for improving selectivity and decreasing defectivity in selective deposition.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### BRIEF SUMMARY

This summary is provided to introduce a selection of concepts in a simplified form. These concepts are described in further detail in the detailed description of examples of the disclosure below. This summary is not intended to necessarily identify key features or essential features of the claimed subject matter, nor is it intended to be used to limit the scope of the claimed subject matter.

In certain examples, described herein are methods, systems and apparatus for the selective deposition of a material on a substrate. The substrate, which may be provided in a reaction chamber, may comprise a first surface with silicon (Si) and a second surface with germanium (Ge). The process may involve selectively depositing a passivation layer on the first surface and an inhibitor on the second surface during cyclic deposition sub-cycles.

The passivation layer may be deposited during a first cyclic deposition sub-cycle by contacting the substrate with a first precursor that may comprise an alkylaminosilane. The alkylaminosilane may comprise at least one of several compounds, including wherein the alkylaminosilane comprises at least one of allyltrimethylsilane (TMS-A), chlorotrimethylsilane (TMS-CI), N-(trimethylsilyl) imidazole (TMS-Im), octadecyltrichlorosilane (ODTCS), hexamethyldisilazane (HMDS), N-(trimethylsilyl)dimethylamine (TMSDMA), trimethylchlorosilane, or 1,1,1-Trimethoxy-N,N-dimethylsilanamine or a combination thereof.

The inhibitor may be deposited during a second cyclic deposition sub-cycle by contacting the substrate with a first inhibitor precursor that may comprise an amine and a second inhibitor precursor that may comprise a dianhydride. In an example, the amine may be a diamine, a triamine, a tetraamine, or a cyclic compound comprising at least two primary amines, or a combination thereof. The dianhydride may be pyromellitic dianhydride (PMDA) or pyromellitic dithioanhydride (PMDTA).

In some examples, the process may further involve purging the reaction chamber and performing the operations in any order until the passivation layer and the inhibitor layer are deposited onto respective ones of the first surface and the second surface of the substrate. This process may be repeated until the passivation layer reaches a first predetermined thickness, or the inhibitor layer reaches a second predetermined thickness, or a combination thereof.

In particular examples, the passivation layer may have a third surface and the inhibitor layer may be selectively deposited relative to this third surface. The first surface may comprise silicon, silicon oxide, silicon nitride, silicon carbide, silicon oxynitride, silicon oxycarbide, or silicon oxycarbonitride, or a combination thereof. The second surface may comprise silicon-germanium (SiGe), with the concentration of germanium being less 50%. In another example, the concentration of germanium may be greater than or equal to 50%. In certain examples, the second surface may also consist substantially of germanium (Ge).

In various examples, the first surface may comprise a first concentration of hydroxyl groups and the second surface may comprise a second concentration of hydroxyl groups that is different from the first concentration wherein the first concentration of hydroxyl groups is less than the second concentration of hydroxyl groups.

In one or more examples, the process may further comprise exposing the substrate to a removal agent and removing the passivation layer and a portion of the inhibitor layer responsive to exposure to the removal agent. The removal agent may be an ozone (O3) gas and/or a plasma comprising one or more of an oxygen-containing plasma, a hydrogen-containing plasma, a nitrogen-containing plasma, or a halide-containing plasma. In an example, the plasma may comprise NH3 plasma, or NF3 plasma. In some embodiments, the plasma may include an inert gas along with the other noted plasmas.

Subsequent to the removing, a material of interest may be selectively deposited on the first surface relative to the second surface. The material of interest may comprise a metal, metal oxide, metal nitride, metal oxynitride, metal carbide, metal oxycarbide, silicon oxide, silicon carbide, silicon nitride, silicon oxynitrides, silicon oxycarbides, a metallic material, elemental metal, metallic surface, or any combination thereof. In some embodiments, the material of interest may comprise: aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr), vanadium (V), aluminum oxide AlOx), cobalt oxide (CoOx), chromium oxide (CrOx), gallium oxide (GaOx), hafnium oxide (HfOx), manganese oxide (M nOx), molybdenum oxide (MoOx), niobium oxide (NbOx), nickel oxide (NiOx), ruthenium oxide (RuOx), tantalum oxide (TaOx), titanium oxide (TiOx), tungsten oxide (WOx), zinc oxide (ZnOx), zirconium oxide (ZrOx), tantalum nitride (TaN), molybdenum nitride (MoNx), tungsten nitride (WNx), aluminum nitride (AlN), titanium nitride (TiN), vanadium carbide (VCx), molybdenum carbide (MoCx), niobium carbide (NbCx), tantalum carbide (TaCx), titanium carbide (TiCx), tungsten carbide (WCx), silicon oxide (SiOx), silicon dioxide (SiO2), silicon carbide (SiC), silicon nitride (SiN), silicon oxycarbide (SiCOx), silicon oxynitride (SiON), silicon oxycarbide (SiOC), silicon oxycarbonitride (SiOCN), or any combination thereof, or any other appropriate material.

The process may further comprise removing the inhibitor layer responsive to exposing the substrate to the removal agent.

The process may include optional pretreatment steps including exposing the substrate to a plasma to remove impurities or residue, or a combination thereof, prior to the selectively depositing the passivation layer and the selectively depositing the inhibitor. The plasma may be an H2 plasma, excited species, hydrogen plasma, hydrogen radicals, or atomic species of hydrogen. The pretreatment process may further comprise contacting the substrate with an oxidizer to hydroxylate the first surface or the second surface, or a combination thereof. The oxidizer may comprise H2O, H2O2, O2 or a plasma of at least one of the following gases O2, O3, CO, or CO2, or a combination thereof. The contacting the substrate with an oxidizer to hydroxylate the first surface or the second surface may also be executed between other operations of the selective deposition process to improve the reactivity of the first or second surfaces.

Other technical features may be readily apparent to one skilled in the art from the following figures, descriptions, and claims.

For the purpose of summarizing the disclosure and the advantages achieved over the prior art, certain objects and advantages of the disclosure have been described herein above. Of course, it is to be understood that not necessarily all such objects or advantages can be achieved in accordance with any particular example or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

All of these examples are intended to be within the scope of the disclosure. These and other examples will become readily apparent to those skilled in the art from the following detailed description of certain examples having reference to the attached figures, the disclosure not being limited to any particular example(s) discussed.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates simplified cross-sectional schematic diagrams of semiconductor structures formed during cyclical selective deposition processes, in accordance with an example of the present technology.

FIG. 4 illustrates a selective deposition process, in accordance with an example of the present technology.

### DETAILED DESCRIPTION

The description of exemplary examples of methods, layers, structures, devices and semiconductor processing assemblies provided below is merely exemplary and is intended for purposes of illustration only. The following description is not intended to limit the scope of the disclosure or the claims. Moreover, recitation of multiple examples having indicated features is not intended to exclude other examples having additional features or other examples incorporating different combinations of the stated features. For example, various examples are set forth as exemplary examples and may be recited in the dependent claims. Unless otherwise noted, the exemplary examples or components thereof may be combined or may be applied separate from each other.

The headings provided herein, if any, are for convenience only and do not necessarily affect the scope or meaning of the claimed subject-matter.

As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some examples, a layer according to the current disclosure is substantially continuous. In some examples, a layer according to the current disclosure is continuous.

In this disclosure, “gas” can include material that is a gas at normal temperature and pressure (NTP), a vaporized solid and/or a vaporized liquid, and can be constituted by a single gas or a mixture of gases, depending on the context. Reactants and precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction chamber, and can include a seal gas.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity.

The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. A reactant may also be a molecule that binds, such as chemisorbs, on the surface of a substrate without undergoing further chemical reactions at the surface with additional precursors and/or reactants. A reactant on a substrate surface may be modified by, for example, thermal or a plasma treatment.

In some examples, a precursor or a reactant is provided in a mixture of two or more compounds. In a mixture, the other compounds in addition to the precursor may be inert compounds or elements. In some examples, a precursor or a reactant is provided in a composition. Composition may be a solution or a gas in standard conditions.

As used herein, the term “comprising” indicates that certain features are included, but that it does not exclude the presence of other features, as long as they do not render the claim unworkable. In some examples, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some examples, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some examples. In this disclosure, any defined meanings do not necessarily exclude ordinary and customary meanings in some examples.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts. Disclosed is a method, system and apparatus for selective deposition of a material on a substrate.

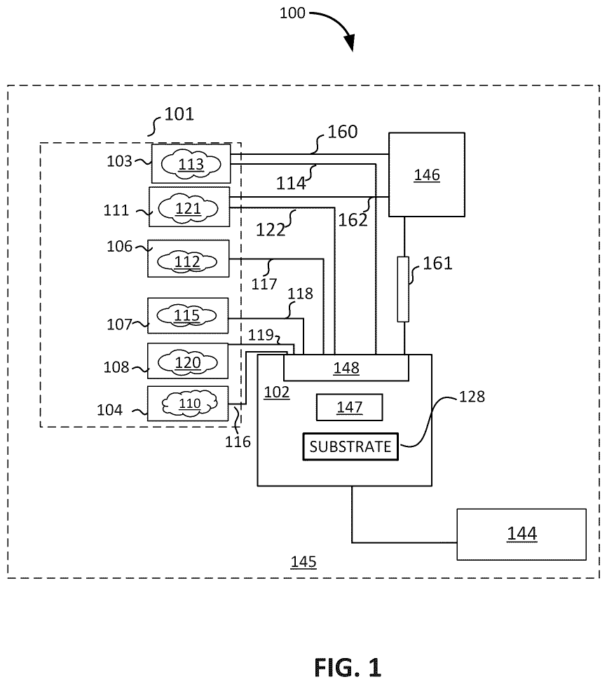

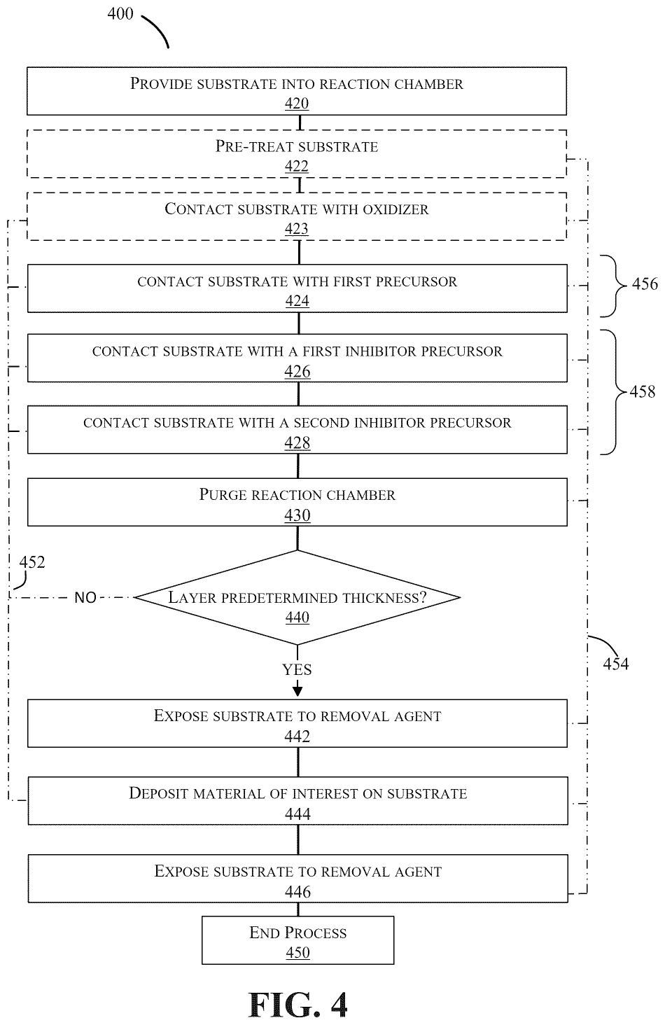

FIG. 1 illustrates a high-level abstraction of a selective deposition assembly 100, in accordance with the present disclosure, depicted schematically. In an example, selective deposition assembly 100 may be configured to perform selective deposition process 400 (see FIG. 4) or one or more sub-cycles of process 400. Specifically, selective deposition assembly 100 may perform one or more sub-cycles of process 400 including but not limited to: a precleaning sub-cycle to prepare substrate 128 for selective deposition, an oxidation step to oxidize a surface of the substrate 128, a first selective deposition sub-cycle for applying passivation material to a first surface and/or second surface of substrate 128, a second selective deposition sub-cycle to apply an inhibitor material onto a second surface of substrate 128, a first removal sub-cycle to remove passivation and/or inhibitor material from substrate 128, a deposition sub-cycle to selectively deposit a material of interest onto the first surface of substrate 128 and/or a second removal sub-cycle to remove inhibitor material from substrate 128.

Process 400 can be executed in one or more selective deposition assemblies, such as selective deposition assembly 100. The complexity of each selective deposition assembly 100 may be determined by the specific sub-cycle(s) of process 400 it is designed to perform. Moreover, each selective deposition assembly 100 can be equipped with only the necessary components to perform its specific sub-cycle or may be equipped with excess components. Assembly 100 may be configured with a variety of components, which may include, but is not limited to, one or more reaction chambers 102, an assortment of source vessels (e.g., source vessels 103, 104, 106, 107, 108, and/or 111) that may contain purge or carrier gases, reactants, oxidizers, etchants, and/or precursor species. These components may be combined in various ways to carry out process 400 and/or designated sub-cycles of process 400.

In the illustrated example, selective deposition assembly 100 includes one or more reaction chambers 102, a precursor injector system 101, a first precursor source vessel 104, an oxidizer source vessel 106, a first inhibitor precursor source vessel 107, a second inhibitor precursor source vessel 108, a removal agent source vessel 111, an exhaust source 144, a remote plasma source 146, a direct plasma source 147, showerhead 148 and a controller 145. The selective deposition assembly 100 may comprise one or more additional gas sources such as a purge and/or carrier gas source vessel 103 containing a carrier gas and/or a purge gas (e.g., an inert gas 113). In an example, remote plasma source 146 maybe coupled to purge and/or carrier gas source vessel 103 via gas line 160 and to removal agent source vessel 111 via gas line 162. Remote plasma source 146 may be coupled to reaction chamber 102 via gas transfer assembly 161 configured to transfer gas from remote plasma source 146 to reaction chamber 102. Reaction chamber 102 can include any suitable reaction chamber, such as an ALD or CVD reaction chamber as described herein.

The purge and/or carrier gas source vessel 103 can include one or more purge and/or carrier gasses as described herein (e.g., inert gas 113). The first precursor source vessel 104 can include one or more first precursors 110 as described herein-alone or mixed with one or more carrier gases. An oxidizer source vessel 106 can include one or more oxidizers 112 as described herein-alone or mixed with one or more carrier gases. A first inhibitor precursor source vessel 107 can include one or more inhibitor precursors 115 as described herein-alone or mixed with one or more carrier gases. A second inhibitor precursor source vessel 108 can include one or more second inhibitor precursors 120 as described herein-alone or mixed with one or more carrier gases. A removal agent source vessel 111 can include one or more removal agents 121 as described herein-alone or mixed with one or more carrier gases.

Although illustrated with source vessels 103, 104, 106, 107, 108 and 111 a selective deposition assembly 100 can include any suitable number of source vessels. Source vessels 103, 104, 106, 107, 108 and 111 can be coupled to reaction chamber 102 via respective lines 114, 116, 117, 118, 119 and 122, which can each include flow controllers, valves, heaters, and the like.

In some examples, the first precursor 110 may be stored in the first precursor source vessel 104, the oxidizer 112 may be stored in the second precursor source vessel 106, the first inhibitor precursor 115 may be stored in the a first inhibitor precursor source vessel 107, second inhibitor precursor 120 may be stored in the second inhibitor precursor source vessel 108 and removal agent 121 may be stored in the removal agent source vessel 111. Source vessels 103, 104, 106, 107, 108 and 111 may be heated.

Exhaust source 144 can include one or more vacuum pumps. Controller 145 includes electronic circuitry and software to selectively operate valves, manifolds, heaters, pumps and other components included in the selective deposition assembly 100. Such circuitry and components operate to introduce precursors, reactants and purge gases from the respective sources.

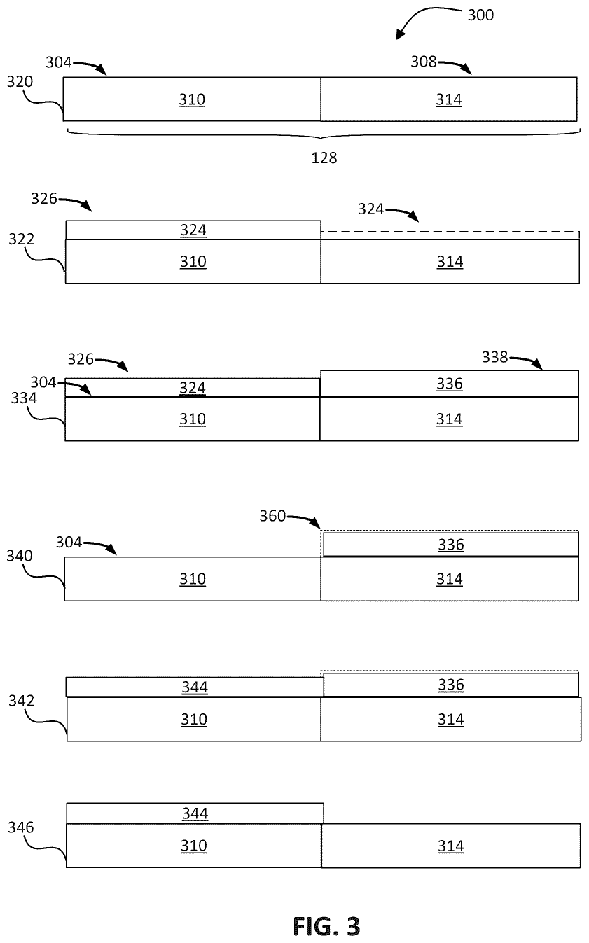

Controller 145 is configured for controlling execution of a selective deposition process as described herein (e.g., processes 300 and 400 described with respect to FIGS. 3 and 4). To that end and for other purposes, controller 145 can control timing of gas pulse sequences, temperature of the substrate and/or reaction chamber 102, pressure within the reaction chamber 102, and various other operations to provide proper operation of the selective deposition assembly 100. Controller 145 can include control software to electrically or pneumatically control valves to control flow of precursors, reactants and purge gases into and out of the reaction chamber 102. Controller 145 can include modules such as a software or hardware component, which performs certain tasks. A module may be configured to reside on the addressable storage medium of the control system and be configured to execute one or more processes.

Other configurations of selective deposition assembly 100 are possible, including different numbers and kinds of precursor and reactant sources. Further, it will be appreciated that there are many arrangements of valves, conduits, precursor sources, and auxiliary reactant sources that may be used to accomplish the goal of selective deposition and in coordinated manner feeding gases into reaction chamber 102. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 100, substrates, such as semiconductor wafer (e.g., substrate 128), are transferred from, e.g., a substrate handling system to reaction chamber 102. Once substrate(s) are transferred to reaction chamber 102, one or more gases from gas sources, such as precursors, reactants, carrier gases, and/or purge gases, are introduced into reaction chamber 102.

In an example, the first precursor 110 may comprise an alkylaminosilane material for depositing a passivation layer as described in greater detail herein.

In an example, the oxidizer 112 may comprise oxidizing material as described in greater detail herein.

In an example, the first inhibitor precursor 115 may comprise an amine (e.g., diamine, triamine, tetraamine and/or cyclic compound comprising at least two primary amine groups), as described in greater detail herein. In an example, second inhibitor precursor 120, may comprise an anhydride, such as furan-2,5-dione (maleic acid anhydride), dianhydride, (e.g., pyromellitic dianhydride (PMDA)) and/or a dianhydride comprising at least one thioanhydride group (e.g., 1,2,4,5-tetrathio-cyclic 1,2:4,5-bis(anhydrosulfide) and/or 1,2,4,5-benzenetetracarboxylic acid (pyromellitic dithioanhydride (PMDTA))) as described in greater detail herein.

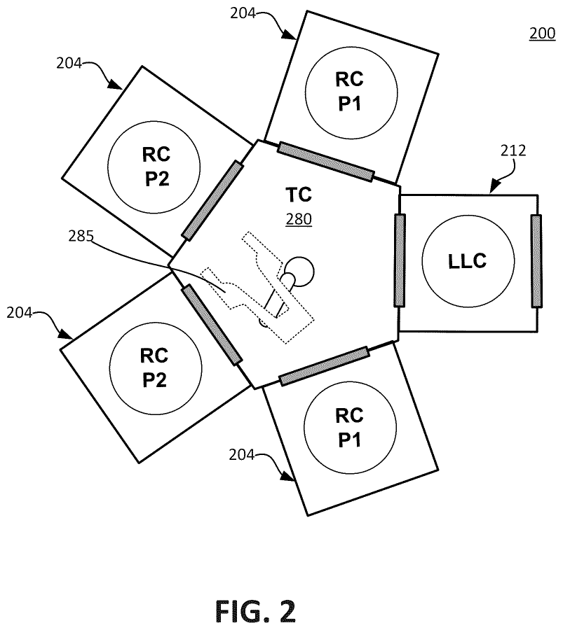

In some examples, a reactor system (e.g., selective deposition assembly 100) can comprise multiple reaction chambers. For example, in reactor system 200, shown in FIG. 2, a number of reaction chambers 204 (each of which can be an example of any of reaction chamber 102 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 128 can be disposed in different chambers for different steps of a semiconductor manufacturing process (e.g., surface clean, passivation, inhibiting, film removal, etching, oxidizing, and/or deposition steps may each be performed in the same or different chambers).

### Substrate

Referring again to FIG. 1, the deposition method according to the current disclosure comprises providing a substrate 128 in reaction chamber 102. The substrate 128 may be any underlying material or materials that can be used to form, or upon which, a structure, a device, a circuit, or a layer can be formed. A substrate 128 can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. Further, the substrate 128 can include various features, such as recesses, protrusions, and the like formed within or on at least a portion of a layer of the substrate 128. For example, a substrate 128 can include bulk semiconductor material and an insulating or dielectric material layer overlying at least a portion of the bulk semiconductor material. Substrate 128 may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. In some examples of the current disclosure, the substrate 128 comprises silicon. The substrate 128 may comprise other materials, as described above, in addition to silicon. The other materials may form layers. Specifically, the substrate 128 may comprise a partially fabricated semiconductor device.

A substrate 128, according to various examples of the current disclosure, includes at least a first surface (e.g., first surface 304, see FIG. 3) and a second surface (e.g., second surface 308, see FIG. 3). These surfaces may possess distinct material properties, which facilitate the selective deposition of a passivation material on the first surface and an organic polymer (for instance, an inhibitor) on the second surface. In certain examples, the first and second surfaces may be adjacent to each other. In some examples, the first surface and the second surface may be located on the same face of a silicon wafer.

In some examples, the substrate 128 may undergo one or more treatments to prepare it for deposition. Initially, the substrate 128 may be pre-cleaned or cleaned before or at the start of the selective deposition process as per the present disclosure. In an example, the substrate 128 may be subjected to a plasma cleaning process before or at the start of the selective deposition process. This plasma cleaning process may involve ion bombardment, exposure to plasma, radicals, excited species, and/or atomic species before or at the start of the selective deposition process. In yet other examples, the substrate 128 surface may be exposed to hydrogen plasma, radicals, or atomic species before or at the start of the selective deposition process. This pre-clean step may be carried out in the same reaction chamber 102 as the selective deposition process or in a different reaction chamber 102.

In some examples, the above-described pre-treatment may remove all or a portion of the active sites, such as hydroxyl groups, from the substrate 128′s surface. To counteract this effect and restore the substrate 128's reactivity, the substrate 128 may be subsequently exposed to an oxidizing agent. The oxidizer is not limited to, but may include, agents such as H2O, H2O2, O2, or a plasma derived from gases like O2, O3, CO, and/or CO2. The choice of oxidizer can be varied to achieve the desired oxidation level on the substrate 128's surface. Additionally, the oxidation process may be integrated into different stages of the selective deposition cycle, potentially occurring during the first cyclic deposition sub-cycle or a second sub-cycle, to optimize the deposition quality and uniformity. The pre-clean step and/or the oxidizer step may be carried out in the same reaction chamber 102 as the selective deposition process or in a different reaction chamber.

### Reaction Chamber

The method of selective deposition of a material of interest on a first surface comprising silicon (e.g., silicon, silicon oxide or silicon nitride) with respect to a second surface comprising silicon germanium (SiGe) or germanium may comprise providing a substrate 128 in a reaction chamber 102. In other words, a substrate 128 is in a space where the deposition conditions can be controlled. The reaction chamber 102 may be a single wafer reactor. Alternatively, the reaction chamber 102 may be a batch reactor. The reaction chamber 102 can form part of a vapor processing assembly for manufacturing semiconductor devices, such as a semiconductor processing assembly. The semiconductor processing assembly may comprise one or more multi-station processing chambers. The reaction chamber 102 may be part of a cluster tool in which different processes are performed to form an integrated circuit. Various phases of the methods according to the current disclosure, such as methods of depositing a passivation layer, an inhibitor, or methods of selectively depositing a metal, metallic and/or dielectric material, can be performed within a single reaction chamber 102, or they can be performed in multiple reaction chambers, such as reaction chambers of a cluster tool, or deposition stations of a multi-station processing chamber.

In some examples, the reaction chamber 102 may be a flow-type reactor, such as a cross-flow reactor. In some examples, the reaction chamber 102 may be a showerhead reactor. In some examples, the reaction chamber 102 may be a hot-wall reactor. In some examples, the reaction chamber 102 may be a space-divided reactor. In some examples, the reaction chamber 102 may be a single-wafer ALD reactor. In some examples, the reaction chamber 102 may be a high-volume manufacturing single-wafer ALD reactor. In some examples, the reaction chamber 102 may be a batch reactor for manufacturing multiple substrate 128s simultaneously.

The reaction chamber 102 of the current disclosure can form part of an atomic layer deposition (ALD) assembly. The reaction chamber 102 can form part of a chemical vapor deposition (CVD) assembly. The processing assembly may be an ALD or a CVD processing assembly. In some parts of the deposition process flow, molecular layer deposition (MLD) may be employed. In some examples, the method is performed in a single reaction chamber 102 of a cluster tool, but other, preceding or subsequent, manufacturing steps of the structure or device are performed in additional reaction chambers of the same cluster tool. Optionally, a semiconductor processing assembly including the reaction chamber 102 can be provided with a heater to activate the reactions by elevating the temperature of one or more of the substrate 128 and/or the reactants and/or precursors.

### Cyclic Vapor Deposition

In some methods according to the current disclosure, particularly those of depositing an organic polymer, and dielectric material, cyclic vapor deposition methods may be used. Cyclic deposition in the current disclosure refers to vapor deposition processes in which deposition cycles, typically a plurality of consecutive deposition cycles, are conducted in a process chamber.

Generally, in cyclic deposition processes according to the current disclosure, such as atomic layer deposition (ALD) and molecular layer deposition (MLD), during each cycle, a precursor is introduced to a reaction chamber 102 and is chemisorbed to a substrate 128 surface (e.g., a substrate 128 surface that may include a previously deposited material from a previous deposition cycle or other material). In some examples, the precursor on the substrate 128 surface does not readily react with additional precursor (i.e., the deposition of the precursor may be a partially or fully self-limiting reaction). Thereafter, another precursor or a reactant may be introduced into the reaction chamber 102 for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber 102. Thus, in some examples, the cyclic deposition process comprises purging the reaction chamber 102 after providing a precursor into the reaction chamber 102. Without limiting the current disclosure to any specific theory, ALD and MLD may be similar processes in terms of self-limiting reactions and slower and more controllable layer growth speed compared to CVD. Generally, ALD is used to deposit inorganic materials, such as a dielectric material, whereas in MLD, the precursors may be fully organic molecules, such as when an organic polymer is deposited.

In some examples, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction chamber 102 or substrate 128, or in partially or completely separated pulses. However, CVD may be performed with a single precursor, or two or more precursors that do not react with each other. A single precursor may decompose into reactive components that are deposited on the substrate 128 surface. The decomposition may be brought about by plasma or thermal means, for example. The substrate 128 and/or reaction chamber 102 can be heated to promote the reaction between the gaseous precursor and/or reactants. In some examples the precursor(s) and reactant(s) are provided until a layer having a desired thickness is deposited. In some examples, cyclic CVD processes can be used with multiple cycles to deposit a thin film having a desired thickness. In cyclic CVD processes, the precursors and/or reactants may be provided to the reaction chamber 102 in pulses that do not overlap, or that partially or completely overlap. The process may comprise one or more cyclic phases. In some examples, the process comprises one or more acyclic (i.e. continuous) phases. An example of a continuous phase could be a pre-treatment with a single reactant. In some examples, the deposition process comprises the continuous flow of at least one precursor. In some examples, one or more of the precursors are provided in the reaction chamber 102 continuously.

According to some aspects of the present disclosure, a selective deposition process or “super-cycle” may be carried out in one or more cyclic deposition sub-cycles. A selective deposition process or “super-cycle” can be used to deposit a material on a first surface relative to a second surface. The two surfaces can have different material properties.

In some examples, in a first cyclic deposition sub-cycle 456 (see FIG. 4) a passivation material may be selectively deposited on a first surface 304 which may comprise silicon. The first surface may be a conducting surface, a semiconducting surface, a non-conducting surface, and/or a dielectric surface. A skilled artisan will understand that not all non-conducting surfaces are dielectric surfaces. In some examples, the first surface may comprise any of a variety of materials including but not limited to silicon, silicon oxide, silicon nitride, silicon carbide, silicon oxynitride, silicon oxycarbide, silicon oxycarbonitride, and/or germanium oxide. In other examples, the first surface 304 may comprise the same basic composition as noted above in the dielectric first surface example but have different material properties due to the manner of formation (e.g., thermal oxides, native oxides, deposited oxides). In some examples, the first surface may comprise SiO₂. In some examples, the first surface may comprise Si—O bonds. In some examples, the first surface may comprise a SiO₂ based low-k material. In some examples, the first surface may comprise more than about 30%, or more than about 50% of SiO₂. In some examples, the first surface may comprise GeO₂.

In some examples, the passivation material may be selectively deposited relative to a different surface of the substrate 128. The different surface may be adjacent to the first surface and may be referred to herein as “a second surface 308.” The second surface 308 may be a conducting surface, a semiconducting surface, a non-conducting surface, and/or a dielectric surface. A skilled artisan will understand that not all non-conducting surfaces are dielectric surfaces. The second surface may comprise silicon and/or germanium (e.g., SiGe or germanium (Ge)). In some examples, the properties of the second surface may vary with the composition of silicon and germanium. For example, the concentration of surface hydroxylates may vary depending on the concentration of germanium in the SiGe or whether silicon is present in a non-negligible amount.

During selective deposition, the concentration of hydroxylated groups on the surface of the first surface relative to the second surface may impact selectivity. In some examples, hydroxyls (OH groups) are often referred to as reactive sites enable surface reactions with various precursors in a self-limiting way. When all the available reactive sites on the surface are consumed surface reactions may terminate. This allows for the precise control of the thickness and composition of the films at the atomic level.

In an example, in a silicon-rich regime the concentration of germanium in the second surface 308 is less than about 50%, or less than about 40%, or less than about 30%, or less than about 20%, or less than about 10%. In this context, “about” means +/−5%. In an example, in a germanium-rich regime, the concentration of germanium in the second surface may be greater than or equal to about 50%, or greater than about 60%, or greater than about 70%, or greater than about 80%, or greater than about 90%. In this context “about” means +/−5%. In some examples, the concentration of germanium in the second surface may be about 100% or in other words may comprise substantially all germanium. In this context “about” means +/−1%.

In another example, exposing the first surface 304 or the second surface 308 to an oxidizer may increase the concentration of active sites and/or hydroxyl groups to improve reactivity of the first surface 304 or the second surface 308. Exposing the first surface 304 or the second surface 308 to the oxidizer may be performed at any appropriate time during the selective deposition process (e.g., process 400, see FIG. 4).

In some examples an inhibitor comprising organic material may be selectively deposited on the second surface 308 relative to the first surface 304 and/or relative to a passivation surface of a passivation layer deposited on the first surface. Such a passivation surface may be referred to herein as “a third surface.”

In some examples, the inhibitor may be an organic material comprising a polyamide, polyimide, or other polymeric material. For example, the second surface 308 may comprise a surface that is substantially electrically non-conducting or has a very high resistivity. In some examples, the second surface 308 may be oxidized. In some examples, selective deposition processes taught herein may deposit on such a non-conductive surface with minimal deposition on adjacent first surface 304.

In some examples the substrate 128 may be pretreated or cleaned prior to or at the beginning of the selective deposition process. In some examples the substrate 128 may be subjected to a plasma cleaning process prior to or at the beginning of the selective deposition process. In some examples a plasma cleaning process may include ion bombardment, exposure to plasma, radicals, excited species, and/or atomic species prior to or at the beginning of the selective deposition process. In some examples the substrate 128 surface may be exposed to hydrogen plasma, radicals, or atomic species prior to or at the beginning of the selective deposition process. In some examples a pretreatment or cleaning process may be carried out in the same reaction chamber 102 as a selective deposition process, however in some examples a pretreatment or cleaning process may be carried out in a separate reaction chamber 102. Selectivity

Selectivity can be given as a percentage calculated by [(deposition on surface A)−(deposition on surface B)]/(deposition on surface A), where surface A and surface B are comprised of different materials. Deposition can be measured in any of a variety of ways. In some examples deposition may be given as the measured thickness of the deposited material. In some examples deposition may be given as the measured amount of material deposited.

In some examples selectivity on first surface 304 with respect to second surface 308 may be greater than about 10%, greater than about 20%, greater than about 30%, greater than about 40%, greater than about 50%, greater than about 60%, greater than about 70%, greater than about 75%, greater than about 80%, greater than about 85%, greater than about 90%, greater than about 93%, greater than about 95%, greater than about 98%, greater than about 99% or even greater than about 99.5%. In examples described herein, the selectivity can change over the duration or thickness of a deposition.

In some examples selectivity on second surface 308 with respect to first surface 304 may be greater than about 10%, greater than about 20%, greater than about 30%, greater than about 40%, greater than about 50%, greater than about 60%, greater than about 70%, greater than about 75%, greater than about 80%, greater than about 85%, greater than about 90%, greater than about 93%, greater than about 95%, greater than about 98%, greater than about 99% or even greater than about 99.5%. In examples described herein, the selectivity can change over the duration or thickness of a deposition.

In some examples deposition only occurs on first surface 304 and does not occur on second surface 308. In some examples deposition on the first surface 304 of the substrate 128 relative to second surface 308 of the substrate 128 is at least about 80% selective, which may be selective enough for some particular applications.

In some examples deposition only occurs on second surface 308 and does not occur on first surface 304. In some examples deposition on the second surface 308 of the substrate 128 relative to first surface 304 of the substrate 128 is at least about 80% selective, which may be selective enough for some particular applications.

In some examples the first passivation layer 324 (see FIG. 3) deposited on the first surface 304 of the substrate 128 may have a thickness less than about 5 angstroms, or less than about 4 angstroms, or less than about 3 angstroms, or less than about 2 angstroms, or less than about 1 angstrom, while a ratio of material deposited on the first surface 304 of the substrate 128 relative to the second surface 308 of the substrate 128 may be greater than or equal to about 20:1, greater than or equal to about 15:1, greater than or equal to about 10:1, greater than or equal to about 5:1, greater than or equal to about 3:1, or greater than or equal to about 2:1.

In some examples the inhibitor layer 336 (see FIG. 3) deposited on the second surface 308 of the substrate 128 may have a thickness less than about 100 nm, or less than about 80 nm, or less than about 60 nm, or less than about 40 nm, or less than about 30 nm, or less than about 20 nm, or less than about 10 nm, or less than about 5 nm, or less than about 2 nm, while a ratio of material deposited on the second surface 308 of the substrate 128 relative to the first surface 304 of the substrate 128 may be greater than or equal to about 20:1, greater than or equal to about 15:1, greater than or equal to about 10:1, greater than or equal to about 5:1, greater than or equal to about 3:1, or greater than or equal to about 2:1.

In some examples the selectivity of the selective deposition processes described herein may depend on the materials which comprise the first and second surface of the substrate 128. Selectivity of a deposition material may be described as a percentage or ratio of the deposition on a first surface vs a second surface even where there are multiple exposed surface materials on a single substrate 128.

### Selective Deposition

FIG. 3 illustrates a process 300 for selective deposition on a substrate 128, wherein operations of process 300 are depicted in cross-sectional views of substrate 128.

In an example, substrate 128 comprises a first material 310 having a first surface 304 and a second material 314 having second surface 308. In an example, first material 310 and second material 314 may be different material.

In an example, first material 310 and/or first surface 304 can comprise an inorganic dielectric, such as a low-k layer (typically a silicon oxide-based layer) or a silicon surface having native oxide (also a form of silicon oxide) formed thereover, for example, first material 310 and/or first surface 304 can comprise SiCOx, SiOx, SiO2, SiC, SiOC, SiON, SiOCN, SiN, Si, high-k material, low-k material, or the like or a combination thereof.

In some examples, the second material 314 and/or second surface 308 may comprise silicon germanium (SiGe) or germanium.

The following description of process 300 is with reference to FIGS. 1 to 3. In an example, process 300 starts at operation 320 wherein a substrate 128 having a first surface 304 and a second surface 308 is supported in a reaction chamber 102 (see FIG. 1). In some examples, first material 310 and second material 314 of substrate 128 may be materially different thus exposed first surface 304 and second surface 308 may be materially different.

Process 300 may continue to operation 322 where selective deposition of a first passivation layer 324 over first surface 304 may be performed. Passivation layer 324 having third surface 326 may be formed selectively on first surface 304 relative to second surface 308.

Process 300 may continue to operation 322 where selective deposition of a first passivation layer 324 over first surface 304 may be performed. Passivation layer 324, having third surface 326, may be formed selectively on first surface 304 relative to second surface 308. In an example, passivation layer 324, characterized by a third surface 326, is preferentially formed on the first surface 304 as opposed to the second surface 308. In certain embodiments, passivation layer 324 may also partially extend over the second surface 308, albeit in a selective manner and, in some instances, to a reduced degree. This selective extension of the passivation layer 324 over the second surface 308 is depicted with dashed lines. It is noted that, due to the selective nature of the passivation layer 324, coverage may be less extensive over the second surface 308 than over the first surface 304.

In an example, selectively depositing the first passivation layer 324 comprises contacting the substrate 128 with a first precursor (e.g., first precursor 110) comprising an alkylaminosilane. In an example, the first precursor 110 may comprise allyltrimethylsilane (TMS-A), 1,1,1-Trimethoxy-N,N-dimethylsilanamine, chlorotrimethylsilane (TMS-CI), N-(trimethylsilyl) imidazole (TMS-Im), octadecyltrichlorosilane (ODTCS), hexamethyldisilazane (HMDS), N-(trimethylsilyl)dimethylamine (TMSDMA) or trimethylchlorosilane, or a combination thereof.

In an example, first precursor 110 may be provided to the reaction chamber 102 holding the substrate 128 to contact substrate 128 with a single pulse or in a sequence of multiple pulses. In some examples the first precursor 110 is provided in a single long pulse or in multiple shorter pulses. The pulses may be provided sequentially. In some examples the first precursor 110 is provided in 1 to 1000 pulses of from about 0.01 to about 600 seconds, or any appropriate number of pulses of any appropriate duration. In between pulses, the first precursor 110 may be removed from the reaction space. For example, the reaction chamber 102 may be evacuated and/or purged with an inert gas. The purge may be, for example for about 0.01 to 600 seconds, or any appropriate pulse period.

In some examples, the temperature of the passivation process may be, for example, from about 25° C. to 500° C., or about 100° C. to about 300° C., or any appropriate temperature. The pressure during the passivation process may be, for example, from about 0.01 to about 760 Torr, or in some examples from about 1 to 10 Torr or about 0.1 to about 10 Torr.

In an example, process 300 may move to operation 334, wherein selective deposition of an inhibitor layer 336 onto second surface 308 may be performed. Inhibitor layer 336, having fourth surface 338, may be formed selectively upon second surface 308 relative to first surface 304. In certain examples, deposition of inhibitor layer 336 is selective to third surface 326 for example, where passivation layer 324 covers first surface 304. Additionally, or alternatively, in an example wherein coverage by passivation layer 324 extends over second surface 308 (described above with respect to operation 322), inhibitor layer 336 may be selectively deposited over passivation layer 324 on second surface 308 with respect to first surface 304. The selectivity may be due to preferential deposition of inhibitor layer 336 over second surface 308 with respect to first surface 304. In some examples, inhibitor layer 336 may displace passivation layer 324 materials disposed over second surface 308. This may be due to coverage of passivation layer 324 over second surface 308 being less extensive than over first surface 304 giving rise to preferential deposition of inhibitor layer 336 over second surface 308 even in the presence of passivation layer 324 on second surface 308.

In an example, inhibitor layer 336 may comprise a polyamide, polyimide, dimer, trimer, polyurethane, polythiourea, polyester, polyimine, or other polymer capable of preferentially forming on second surface 308.

In an example, selectively depositing the inhibitor layer 336 comprises contacting the substrate 128 with a first inhibitor precursor (e.g., first inhibitor precursor 115) comprising an amine such as a diamine (e.g., 1,6-diamnohexane (DAH)), a triamine (e.g., tris(aminoethyl)methylsilane), a tetraamine (e.g., 2,2-bis(aminomethyl)-1,3-propanediamine) and/or a cyclic compound comprising at least two primary amine groups and contacting the substrate with a second inhibitor precursor (e.g., second inhibitor precursor 120) comprising an anhydride, such as furan-2,5-dione (maleic acid anhydride), a dianhydride (e.g., pyromellitic dianhydride (PMDA) and/or pyromellitic dithioanhydride (PMDTA)), or any other species with two reactive groups which will react with the first inhibitor precursor. Such first inhibitor precursors and second inhibitor precursors are disclosed in U.S. Patent Application Ser. No. 63/546,475, filed Oct. 30, 2023, the entire disclosure of which is incorporated herein by reference for all purposes. Additional or alternative example processes for selectively depositing such an inhibitor layer 336 comprising polyamide or polyimide by vapor deposition techniques are disclosed in U.S. Pat. No. 10,373,820 issued Aug. 6, 2019, the entire disclosure of which is incorporated herein by reference for all purposes.

In an example, process 300 may move to operation 340, where passivation layer 324 may be removed. Substrate 128 is shown at operation 340 after removal of the passivation layer 324 from first surface 304 and a portion 360 (shown in dotted line) of inhibitor layer 336 from second surface 308.

In an example, passivation layer 324 may be removed by heat treatment at temperatures lower than those that would remove a polymer layer comprising inhibitor layer 336.

In another example, passivation layer 324 may be completely or almost completely removed by exposing the substrate 128 to a removal agent (e.g., removal agent 121). In certain examples the removal agent may be an etchant (e.g., NF3), a plasma, or ozone (O3) gas. In certain examples, a plasma may comprise at least one of an oxygen-containing plasma, a hydrogen-containing plasma, a nitrogen-containing plasma, or a halide-containing plasma. In some examples, removal agent 121 may comprise a plasma including but not limited to: oxygen-containing species such as oxygen atoms, oxygen radicals, and oxygen plasma; a hydrogen-containing species including hydrogen atoms, hydrogen radicals, and hydrogen plasma; a nitrogen-containing species including nitrogen atoms, nitrogen radicals, and nitrogen plasma; specific molecular entities and corresponding plasmas, namely NH3 molecules and NH3 plasma, NF3 molecules and NF3 plasma; and various other plasma types including O2 plasma, O3 plasma, carbon monoxide (CO) plasma, and carbon dioxide (CO2) plasma. In some examples, the plasma may comprise inert gas species (e.g., argon (Ar), nitrogen (N2), and/or helium (He)), alone or in combination with a non-inert species such as, but not limited to those plasma species listed hereinabove.

In some examples, the removal process may comprise exposing the substrate to an etchant comprising oxygen, for example O3. In some examples, the substrate may be exposed to an etchant at a temperature of between about 25° C. and about 500° C., preferably between about 100° C. and about 400° C. In some examples, the etchant may be supplied in one continuous pulse or may be supplied in multiple shorter pulses.

As noted above, in some examples, O3 (e.g. O3/N2) can be used in the etch process for removal of passivation layer 324 and/or a portion of inhibitor layer 336. In some examples, the removal process may be performed at a substrate temperature of about 25° C. to about 500° C.

In some examples, the removal process may be performed at a rate of about 0.001 nm/min to about 500.0 nm/min. In some examples, the removal process may be performed at a rate of about 0.1 nm/min to about 5.0 nm/min. In some examples for single wafer or small batch (e.g., 5 wafers or less) processing, a low O₃ concentration etch process may be used, wherein the low O₃ concentration etch process is performed at 0.01 Torr to 760 Torr, more particularly about 0.1 Torr to 100 Torr (e.g., 2 Torr). Ozone pulsing can be between 0.001 sec and 1800 seconds, particularly between 1 sec and 50 sec. O₃ flow can range from 0.001 slm to 50 slm, more particularly from 0.1 sim to 1 slm. Inert (e.g., N₂) carrier gas flow of can range from 0.001 slm to 50 sim, more particularly from 0.1 slm to 1 slm.

Process 300 may proceed to operation 342, wherein subsequent to the removing, a material layer of interest (referred to herein as “material layer 344”) may be selectively deposited on the first surface 304 relative to the second surface 308 and/or fourth surface 338. Material layer 344 may be deposited on first surface 304 or (if exposed) a portion of second surface 308, or a combination thereof. Most of surface 308 may remain covered by inhibitor layer 336 and thus material layer 344 will not cover unexposed areas of second surface 308.

In various examples, material layer 344 may comprise any of a variety of materials. For example, material layer 344 may comprise one or more of a metal, metal oxide, metal nitride, metal oxynitride, metal carbide, metal oxycarbide, silicon oxide, silicon carbide, silicon nitride, silicon oxynitrides, silicon oxycarbides, including but not limited to: aluminum oxide (AlOx), cobalt oxide (CoOx), chromium oxide (CrOx), gallium oxide (GaOx), hafnium oxide (HfOx), manganese oxide (M nOx), molybdenum oxide (MoOx), niobium oxide (NbOx), nickel oxide (NiOx), ruthenium oxide (RuOx), tantalum oxide (TaOx), titanium oxide (TiOx), tungsten oxide (WOx), zinc oxide (ZnOx), zirconium oxide (ZrOx), tantalum nitride (TaN), molybdenum nitride (MoNx), tungsten nitride (WNx), aluminum nitride (AlN), titanium nitride (TiN), vanadium carbide (VCx), molybdenum carbide (MoCx), niobium carbide (NbCx), tantalum carbide (TaCx), titanium carbide (TiCx), tungsten carbide (WCx), silicon oxide (SiOx), silicon dioxide (SiO2), silicon carbide (SIC), silicon nitride (SiN), silicon oxycarbide (SiCOx), silicon oxynitride (SiON), silicon oxycarbide (SiOC), silicon oxycarbonitride (SiOCN), or any combination thereof, or any other suitable material.

In certain examples, material layer 344 may comprise a metallic material, elemental metal, metallic surface, or any combination thereof. In various examples, material layer 344 may comprise aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr), vanadium (V), or any combination thereof.

In an example, process 300 may move to operation 346, where inhibitor layer 336 may be removed. In an example, a remaining portion of the inhibitor layer 336 may be completely or almost completely removed by exposing the substrate 128 to a removal agent (e.g., removal agent 121) at an appropriate temperature and pressure. In certain examples the removal agent may be an H2 plasma or O3 or the same or similar methods described above with respect to operation 340 to remove passivation layers. Layer 336 may require additional time and power for removal compared to passivation layer 324.

In particular examples, surfaces 304 and 308 may comprise various topologies within a device including but not limited to 2D or 3D structures, within a gap feature, where surfaces 304 and 308 are parallel, and/or at various angles to one another and/or adjacent to one another and/or in repeating patterns, or the like or combinations thereof.

FIG. 4 illustrates an example process 400 for selective deposition of a material of interest on a substrate 128 according to examples of the current disclosure. In an example, process 400 may comprise providing a substrate (e.g., substrate 128 shown in FIG. 3) in a reaction chamber (e.g., reaction chamber 102 shown in FIG. 1), wherein the substrate comprises a first surface (e.g., first surface 304 shown in FIG. 3) and a second surface (e.g., second surface 308 shown in FIG. 3). The first surface may comprise silicon and the second surface may comprise SiGe or Ge. The first surface may be materially different from the second surface. The selective deposition process 400 may further comprise depositing a first passivation layer (e.g., first passivation layer 324 shown in FIG. 3) having a third surface on first surface 304 and depositing an inhibitor layer (e.g., inhibitor layer 336 shown in FIG. 3) having a fourth surface on second surface 308. The first surface, second surface, third surface and fourth surface may be materially different substances. In an example, selective deposition of the first passivation layer and/or the inhibitor layer may occur in any order.

The selective deposition process 400 may further comprise removing the first passivation layer and/or removing the inhibitor layer. The selective deposition process 400 may further comprise depositing a material of interest layer (e.g., material layer 344 shown in FIG. 3) over the first surface and/or the second surface. In an example, selective removal of the first passivation layer and/or the inhibitor layer may occur in any order.

In an example, process 400 may begin at operation 420, where a substrate may be provided in a reaction chamber 102.

In an example, process 400 may move to an optional operation 422, where the substrate may be pretreated. In an example, at operation 422 substrate surface (e.g., including first surface 304 and second surface 308) may be exposed to a plasma species (e.g., H2 plasma) to remove contaminants such as oxides, etch residue, and other processing residues that can reduce effectiveness of further processing and/or the performance of the final product. In certain examples, the plasma may comprise a removal agent (e.g., removal agent 121). In some examples, the plasma may be any appropriate plasma species including but not limited to: oxygen-containing species such as oxygen atoms, oxygen radicals, and oxygen plasma; hydrogen-containing species including hydrogen atoms, hydrogen radicals, and hydrogen plasma; nitrogen-containing species including nitrogen atoms, nitrogen radicals, and nitrogen plasma; specific molecular entities and corresponding plasmas, namely NH3 molecules and NH3 plasma, NF3 molecules and NF3 plasma; and various other plasma types including O2 plasma, O3 plasma, carbon monoxide (CO) plasma, and carbon dioxide (CO2) plasma. In some examples, the plasma may comprise inert gas species (e.g., argon (Ar), nitrogen (N2), and/or helium (He)), alone or in combination with a non-inert species such as, but not limited to, those plasma species listed hereinabove.

In an example, process 400 may move to an optional operation 423, where the substrate may be exposed to an oxidizer (e.g., oxidizer 112, see FIG. 1). During plasma treatment in operation 422, hydroxyl groups may be depleted from the surface of substrate 128. Exposing the substrate surface to an oxidizer may re-hydroxylate the surface of substrate 128. Oxidizers 112 may include water (H2O), hydrogen peroxide (H2O2), oxygen (O2), nitric oxide (NO), nitrogen dioxide (NO2), nitrous oxide (N2O), O2 plasma, O3 plasma, CO plasma, or CO2 plasma, or a combination thereof. In an example, exposing the first surface 304 or the second surface 308 to an oxidizer may increase the concentration of active sites and/or hydroxyl groups to improve reactivity of the first surface 304 or the second surface 308. As indicated with dashed lines, exposing the first surface 304 and/or the second surface 308 to the oxidizer 112 may be performed at any appropriate time during the selective deposition process.

Process 400 may move to operation 424, where a first precursor (e.g., first precursor 110 shown in FIG. 1) comprising an alkylaminosilane may contact the substrate to selectively deposit the first passivation layer on the first surface 304 relative to the second surface 308. In an example, operation 424 may be repeated until passivation layer 324 reaches a first predetermined thickness in the range of about 1 angstrom or less.

In an example, process 400 may proceed to operations 426 and 428, where a first inhibitor precursor (e.g., first inhibitor precursor 115 shown in FIG. 1) comprising an amine may contact the substrate and a second inhibitor precursor (e.g., second inhibitor precursor 120 shown in FIG. 1) comprising a dianhydride may contact the substrate to selectively deposit an inhibitor layer on the second surface 308 of substrate 128 relative to the first surface 304 of substrate 128 and the third surface 326 of passivation layer 324. In an example, operations 426 and 428 may be repeated until inhibitor layer 336 reaches a second predetermined thickness in the range of about 0.01 angstrom to 100 nm.

In an example, process 400 may proceed to operation 430 where the reaction chamber 102 may be purged by pulsing purge gas (e.g., purge gas 113) into the reaction chamber 102. In an example, cyclical deposition process 400 as described herein can comprise one or more purges. As illustrated with dashed line 454, one or more purges can precede, separate, and/or follow one or more of operations 422, 423, 424, 426, and/or 428. A purge operation 430 may intermittently expose the substrate to a purge gas. Suitable purge gasses include inert or substantially inert gasses. In some examples, the purge gas comprises one or more of N2 and/or a noble gas. Suitable noble gasses include He, Ne, Ar, Kr, and Xe.

In an example, process 400 may include performing operations 423, 424, 426, 428 or 430 or any combination thereof, in any order, any number of times until the respective first passivation layer and/or inhibitor layer reach respective predetermined thicknesses at operation 440. Operations 423, 424, 426, 428 and/or 430 or any combination thereof may be performed cyclically until the predetermined thickness of passivation layer and/or inhibitor layer has been achieved. This is indicated with dashed line 452.

In an example, process 400 may proceed to operation 442 where the substrate may be exposed to a removal agent to remove the first passivation layer and/or a portion of the inhibitor layer responsive to exposure to the removal agent 121. In an example, the removal agent 121 may be any of a variety of removal agents as discussed in greater detail hereinabove.

In an example, process 400 may proceed to operation 444 where a material of interest (see “material layer” 344 in FIG. 3) may be deposited over the first surface 304 and in some embodiments over a portion of the second surface 308. Material layer 344 may comprise a variety of materials as described hereinabove in greater detail.

In an example, process 400 may proceed to operation 446 where the substrate may be exposed to a removal agent to remove inhibitor layer 336 responsive to exposure to the removal agent 121. In an example, the removal agent 121 may comprise any of a variety of removal agents as discussed in greater detail hereinabove.

In an example, process 400 may return to operation 430 where the reaction chamber 102 may be purged by pulsing purge gas (e.g., purge gas 113) into the reaction chamber 102. In an example, cyclical deposition process 400 as described herein can comprise one or more purges. As illustrated with dashed line 454, one or more purges can precede, separate, and/or follow one or more of operations 442, 444, and/or 446. A purge operation 430 may intermittently expose the substrate to a purge gas. Suitable purge gasses include inert or substantially inert gasses. In some examples, the purge gas comprises one or more of N2 and/or a noble gas. Suitable noble gasses include He, Ne, Ar, Kr, and Xe.

In an example, process 400 may proceed to operation 450 where the process may end.

Process 400 may be a selective deposition “super-cycle” comprising a multiple selective deposition “sub-cycles” including, but not limited to: a “pretreatment sub-cycle” comprising operations 422 and/or operation 423; a “first cyclic deposition sub-cycle 456” comprising operation 424; a “second cyclic deposition sub-cycle 458” comprising operation 426 and operation 428; a “first removal sub-cycle” comprising operation 442; a “third cyclic deposition sub-cycle” comprising operation 444; a “second removal sub-cycle” comprising operation 446. The above described sub-cycles may be repeated as described above any number and/or may be separated by purge operations.

A skilled artisan can readily determine the optimal exposure time, temperature, and power for removing the desired amount of deposited organic material from the substrate.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various processes, systems, and configurations, and other features, functions, acts, and/or properties disclosed herein, as well as any and all equivalents thereof.

1. A process for selective deposition of a material on a substrate, comprising:
providing the substrate in a reaction chamber, the substrate comprising a first surface comprising silicon (Si) and a second surface comprising germanium (Ge);
selectively depositing a passivation layer on the first surface with respect to the second surface responsive to:
a) contacting the substrate with a first precursor comprising an alkylaminosilane during a first cyclic deposition sub-cycle;
selectively depositing an inhibitor layer on the second surface relative to the first surface during a second cyclic deposition sub-cycle responsive to:
b) contacting the substrate with a first inhibitor precursor comprising an amine; and
c) contacting the substrate with a second inhibitor precursor comprising a dianhydride.

2. The process of claim 1, further comprising:
d) purging the reaction chamber; and
performing at least one of operations a), b), c) or d) in any order, until the passivation layer and the inhibitor layer are deposited onto respective ones of the first surface and the second surface.

3. The process of claim 2, further comprising:
repeating the performing the at least one of operations a), b), c), or d) in any order, until the passivation layer reaches a first predetermined thickness, or the inhibitor layer reaches a second predetermined thickness, or a combination thereof.

4. The process of claim 1, wherein:
the passivation layer has a third surface and wherein the inhibitor layer is selectively deposited relative to the third surface.

5. The process of claim 1, wherein the first surface comprises silicon, silicon oxide, silicon nitride, silicon carbide, silicon oxynitride, silicon oxycarbide, or silicon oxycarbonitride, or a combination thereof.

6. The process of claim 1, wherein the second surface comprises silicon-germanium (SiGe).

7. The process of claim 6, wherein a concentration of the germanium in the second surface is less than 50%.

8. The process of claim 6, wherein a concentration of the germanium in the second surface is greater than or equal to 50%.

9. The process of claim 1, wherein the second surface consists substantially of the germanium (Ge).

10. The process of claim 1, wherein the first surface comprises a first concentration of hydroxyl groups and the second surface comprises a second concentration of hydroxyl groups that is different from the first concentration of hydroxyl groups.

11. The process of claim 10, wherein the first concentration of hydroxyl groups is less than the second concentration of hydroxyl groups.

12. The process of claim 1, wherein the alkylaminosilane comprises at least one of allyltrimethylsilane (TMS-A), chlorotrimethylsilane (TMS-CI) , N-(trimethylsilyl)imidazole (TMS-Im) , octadecyltrichlorosilane (ODTCS) , hexamethyldisilazane (HMDS), N-(trimethylsilyl)dimethylamine (TMSDM A), trimethylchlorosilane, or 1,1,1-Trimethoxy-N,N-dimethylsilanamine or a combination thereof.

13. The process of claim 1, wherein the amine is a diamine, a triamine, a tetraamine, or a cyclic compound comprising at least two primary amines, or a combination thereof.

14. The process of claim 1, wherein the dianhydride is pyromellitic dianhydride (PMDA) or pyromellitic dithioanhydride (PMDTA).

15. The process of claim 1, further comprising:
exposing the substrate to a first removal agent; and
removing the passivation layer or a portion of the inhibitor layer, or a combination thereof, responsive to exposure to the removal agent.

16. The process of claim 15, wherein the removal agent is a plasma comprising at least one of an oxygen-containing plasma, a hydrogen-containing plasma, a nitrogen-containing plasma, or a halide-containing plasma.

17. The process of claim 16, wherein the plasma includes an inert gas.

18. The process of claim 15, wherein the removal agent is ozone (O3).

19. The process of claim 15, further comprising subsequent to the removing, selectively depositing a material of interest on the first surface relative to the second surface.

20. The process of claim 19, wherein the material of interest comprises a metal, metal oxide, metal nitride, metal oxynitride, metal carbide, metal oxycarbide, silicon oxide, silicon carbide, silicon nitride, silicon oxynitrides, silicon oxycarbide, a metallic material, elemental metal, metallic surface, or any combination thereof.

21. The process of claim 20, wherein the material of interest comprises aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr), vanadium (V), aluminum oxide (AlOx), cobalt oxide (CoOx), chromium oxide (CrOx), gallium oxide (GaOx), hafnium oxide (HfOx), manganese oxide (MnOx), molybdenum oxide (MoOx), niobium oxide (NbOx), nickel oxide (NiOx), ruthenium oxide (RuOx), tantalum oxide (TaOx), titanium oxide (TiOx), tungsten oxide (WOx), zinc oxide (ZnOx), zirconium oxide (ZrOx), tantalum nitride (TaN), molybdenum nitride (MoNx), tungsten nitride (WNx), aluminum nitride (AlN), titanium nitride (TiN), vanadium carbide (VCx), molybdenum carbide (MoCx), niobium carbide (NbCx), tantalum carbide (TaCx), titanium carbide (TiCx), tungsten carbide (WCx), silicon oxide (SiOx), silicon dioxide (SiO2), silicon carbide (SiC), silicon nitride (SiN), silicon oxycarbide (SiCOx), silicon oxynitride (SiON), silicon oxycarbide (SiOC), silicon oxycarbonitride (SiOCN), or any combination thereof.

22. The process of claim 19, further comprising subsequent to selectively depositing the material of interest, removing the inhibitor layer responsive to exposing the substrate to a second removal agent.

23. The process of claim 1, further comprising exposing the substrate to a plasma to remove impurities or residue, or a combination thereof, prior to the selectively depositing the passivation layer and the selectively depositing the inhibitor layer.

24. The process of claim 23, wherein the plasma may be an H2 plasma, excited species, hydrogen plasma, hydrogen radicals, or atomic species of hydrogen.

25. The process of claim 1, further comprising contacting the substrate with an oxidizer to hydroxylate the first surface or the second surface, or a combination thereof.

26. The process of claim 25, wherein the contacting the substrate with the oxidizer is performed prior to the selectively depositing the passivation layer and the selectively depositing the inhibitor layer.

27. The process of claim 25, wherein the oxidizer comprises H2O, H2O2, O2 or a plasma of at least one of the following gases O2, O3, CO, or CO2, or a combination thereof.
